(19) United States
(12) Patent Application Publication
(10) Pub. No.: US 2017/0254934 A1
(43) Pub. Date: Sep. 7, 2017

(54) METHOD FOR PATTERNING QUANTUM DOT LAYER AND METHOD FOR MANUFACTURING QUANTUM DOT COLOR FILTER

(71) Applicant: Shenzhen China Star Optoelectronics Technology Co. Ltd., Shenzhen City (CN)

(72) Inventors: Yuheng Liang, Shenzhen City (CN); Guohe Liu, Shenzhen City (CN)

(21) Appl. No.: 14/908,133

(22) PCT Filed: Dec. 21, 2015
(86) PCT No.: PCT/CN2015/098142

§ 371 Date: Jan. 28, 2016

(30) Foreign Application Priority Data
Oct. 8, 2015 (CN) 201510646006.0

(51) Int. Cl. G02B 5/20; G03F 7/26; G03F 7/16; G03F 7/20; G02F 1/1335; G03F 7/00

(52) U.S. Cl. CPC G02B 5/201; G02F 1/133516; G02F 1/133617; G03F 7/0007; G03F 7/16; G03F 7/20; G03F 7/26; Y10S 977/774; B82Y 20/00

(57) ABSTRACT

The present invention provides a method for patterning a quantum dot layer and a method for manufacturing a quantum dot color filter. The method for patterning a quantum dot layer according to the present invention uses a photoresist layer having a patterned structure as a shielding layer to subject a monocolor quantum dot layer to etching to form a patterned quantum dot layer. The method simplifies the constituent components for making a quantum dot paste that is used to form a quantum dot layer and simplifying a surface chemical environment of the quantum dots to thereby increasing light emission efficiency of the quantum dot. Further, the method may manufacture a fine quantum dot pattern, greatly improving the resolution of the patterned quantum dot layer. The method for manufacturing a quantum dot color filter according to the present invention is applied to manufacturing a quantum dot color filter on the basis of the above-described method for patterning a quantum dot layer and the quantum dot color filter so manufactured has a fine quantum dot pattern, the light emission efficiency of the quantum dots being high to thereby effectively improve the resolution and backlighting utilization of a display device.

### BACKGROUND OF THE INVENTION

1. Field of the Invention

The present invention relates to the field of display technology, and in particular to a method for patterning a quantum dot layer and a method for manufacturing a quantum dot color filter.

2. The Related Arts

With the continuous development of the display technology, people increasingly demand higher and higher quality of displaying. Quantum dots (QDs) are nanometer semiconductor particles in the form of spheres or similar to spheres made of elements of II-VI groups or III-V groups, having a particle size between several nanometers and tens of nanometers. Since the particle size of QDs is less than or close to the exciton Bohr radius of the corresponding material, an quantum confinement effect is generally involved, where the energy band structure is changed from quasi-continuity of the body material to the discrete structure of the quantum dot material, making the quantum dots exhibiting unique behavior of stimulated emission of light. When the size of the QDs is decreased, the energy band gap becomes increased so that the energy required for exciting the QDs and the energy released from the excited QDs returning back to the ground state are increased correspondingly, exhibiting a “blue-shifting” phenomenon of the excitation of the QDs and the fluorescent spectrum. By controlling the size of the QDs, the emission spectrum thereof may be made covering the entire range of visible light. For example, when the size of cadmium selenide is decreased from 6.6 nm to 2.0 nm, the luminescence wavelength “blue-shifts” from red light zone of 635 nm to blue light zone of 460 nm.

Quantum dot materials have advantages, such as concentrated luminescence spectrum, high color purity, and luminescence color being easily adjustable through the size, structure, or composition of the quantum dot materials. Such advantages allow for applications in display devices to effectively improve the color gamut and color restorability of the display devices. For example, patent documents including CN 102944943 A and US 2015/0002788 A1 propose technical solutions of using quantum dot layers having a pattern structure to replace color filters for color displaying. However, such patent documents do not disclose the ways of patterning the quantum dot layers

Patent document CN 103226260 A proposes a method dispersing quantum dots in a photoresist and applying a photoresist processing operation to pattern a quantum dot layer. However, in dispersing the quantum dots in the photoresist, due to various high molecule substances, such as initiation agents, monomers, polymers, and additives, involved in the photoresist, chemical environments on surfaces of the quantum dots may become complicated, leading to a great influence on the light emission efficiency of the quantum dots. Besides the above-discussed method, a quantum dot pattern may be formed through transfer-printing and screen printing. However, the quantum dot patterns formed with transfer-printing have poor resolution, where edges of the patterns are in a serrated form and the adhering power between the quantum dot layer and the base requires being further improved. Inkjet printing is also a method for forming a patterned quantum dot layer and such a method has a severe requirement for the inkjet printing device. There is still technical barrier to maintain stability of the drops of ink jet and the precision of printing, making it not possible for use in mass production.

### SUMMARY OF THE INVENTION

An object of the present invention is to provide a method for patterning a quantum dot layer, which is capable of forming a fine quantum dot pattern; and the method helps simplify a surface chemical environment of a quantum dot to thereby increase light emission efficiency of the quantum dot.

Another object of the present invention is to provide a method for manufacturing a quantum dot color filter, which is capable of forming a fine quantum dot pattern; and the method helps simplify a surface chemical environment of a quantum dot to thereby increase light emission efficiency of the quantum dot and thus improve resolution and backlighting utilization of a display device.

To achieve the above objects, the present invention provides a method for patterning a quantum dot layer, which comprises the following steps:

(1) providing a base plate and coating a monocolor quantum dot paste on the base plate so as to obtain a monocolor quantum dot layer after curing, the monocolor quantum dot layer emitting monochromatic light of a color corresponding thereto upon excited by external light;

(2) coating a photoresist on the monocolor quantum dot layer to form a photoresist film and applying a mask to subject the photoresist film to exposure and development and baking so as to form a photoresist layer; and

(3) using the photoresist layer as a shielding layer to subject the monocolor quantum dot layer to etching for removing a portion of the monocolor quantum dot layer that is not shielded by the photoresist layer so as to form a patterned monocolor quantum dot layer.

The monocolor quantum dot paste comprises curable paste and monocolor quantum dots mixed in the curable paste; the curable paste comprises heat curable paste or ultraviolet curable paste; and in step (1), the curing is achieved with a heat curing process or an ultraviolet curing process.

The monocolor quantum dot paste comprises a monocolor quantum dot material that comprises one of II-VI group quantum dot materials and I-III-VI group quantum dot materials or multiple ones thereof.

The monocolor quantum dot material of the monocolor quantum dot paste comprises one of CdSe, CdS, CdTe, ZnS, ZnSe, CuInS, and ZnCuInS or multiple ones thereof.

The monocolor quantum dot layer has a thickness of 1-50 μm; optionally, the photoresist comprises a transparent material; and the etching of the monocolor quantum dot layer in step (3) is conducted with dry etching or wet etching.

Optionally, the photoresist comprises a non-transparent material, and the method for patterning a quantum dot layer further comprises:

(4) applying a peeling agent to peel the photoresist layer from the patterned monocolor quantum dot layer.

The present invention also provides a method for manufacturing a quantum dot color filter, comprising the following steps:

(1) providing a base plate, the base plate comprising a red sub-pixel zone, a green sub-pixel zone, and a blue sub-pixel zone; and

(2) forming, on the base plate, a patterned red quantum dot layer corresponding to the red sub-pixel zone; a patterned green quantum dot layer corresponding to the green sub-pixel zone; and a patterned blue quantum dot layer or an organic transparent photoresist layer corresponding to the blue sub-pixel zone,

wherein the patterned red quantum dot layer, the patterned green quantum dot layer, and the patterned blue quantum dot layer are formed with the above-described method for patterning a quantum dot layer by respectively applying a red quantum dot paste, a green quantum dot paste, and a blue quantum dot paste.

Optionally, the quantum dot color filter is applicable to a display device having blue backlighting and in step (2), an organic transparent photoresist layer is formed to correspond to the blue sub-pixel zone.

The method for manufacturing a quantum dot color filter further comprises: step (3) forming a blue light filter layer on each of the patterned red quantum dot layer and the patterned green quantum dot layer.

Optionally, the quantum dot color filter is applicable to a display device having ultraviolet backlighting and in step (2), a patterned blue quantum dot layer is formed to correspond to the blue sub-pixel zone.

The efficacy of the present invention is that the present invention provides a method for patterning a quantum dot layer and a method for manufacturing a quantum dot color filter. The method for patterning a quantum dot layer according to the present invention uses a photoresist layer having a patterned structure as a shielding layer to subject a monocolor quantum dot layer to etching to form a patterned quantum dot layer. The method simplifies the constituent components for making a quantum dot paste that is used to form a quantum dot layer and simplifying a surface chemical environment of the quantum dots to thereby increasing light emission efficiency of the quantum dot. Further, the method may manufacture a fine quantum dot pattern, greatly improving the resolution of the patterned quantum dot layer. The method for manufacturing a quantum dot color filter according to the present invention is applied to manufacturing a quantum dot color filter on the basis of the above-described method for patterning a quantum dot layer and the quantum dot color filter so manufactured has a fine quantum dot pattern, the light emission efficiency of the quantum dots being high to thereby effectively improve the resolution and backlighting utilization of a display device.

### BRIEF DESCRIPTION OF THE DRAWINGS

The technical solution, as well as other beneficial advantages, of the present invention will become apparent from the following detailed description of an embodiment of the present invention, with reference to the attached drawings.

In the drawings:

FIG. 1 is a flow chart illustrating a method for patterning a quantum dot layer according to the present invention;

FIG. 2 is a schematic view illustrating step 1 of the method for patterning a quantum dot layer according to the present invention;

FIG. 3 is a schematic view illustrating coating of a photoresist on a monocolor quantum dot layer carried out in step 2 of the method for patterning a quantum dot layer according to the present invention;

FIG. 4 is a schematic view illustrating exposure of the photoresist carried out in step 2 of the method for patterning a quantum dot layer according to the present invention;

FIG. 5 is a schematic view illustrating development of the exposed photoresist carried out in step 2 of the method for patterning a quantum dot layer according to the present invention;

FIG. 6 is a schematic view illustrating step 3 of the method for patterning a quantum dot layer according to the present invention;

FIG. 7 is a schematic view illustrating step 4 of the method for patterning a quantum dot layer according to the present invention;

FIG. 8 is a schematic view illustrating step 2 of a first example of a method for manufacturing a quantum dot color filter according to the present invention;

FIG. 9 is a schematic view illustrating step 2 of a second example of the method for manufacturing a quantum dot color filter according to the present invention; and

FIG. 10 is a schematic view illustrating step 3 of the second example of the method for manufacturing a quantum dot color filter according to the present invention.

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

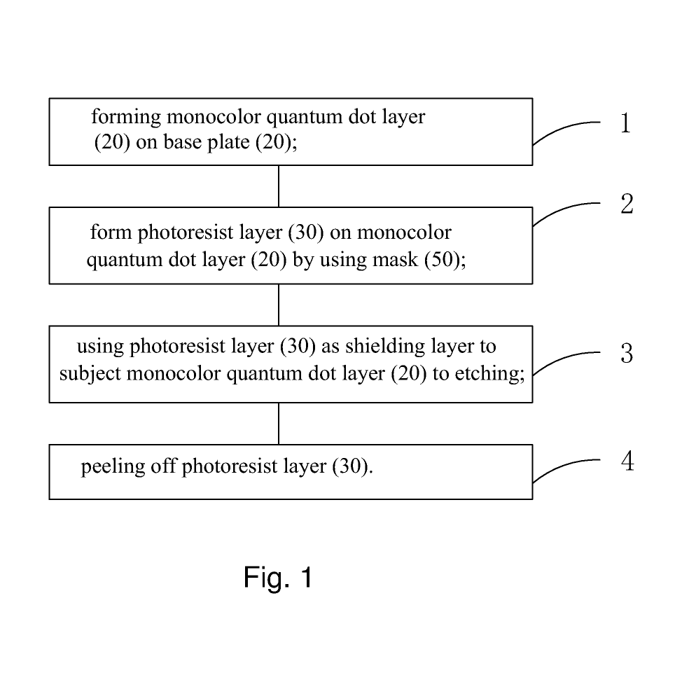

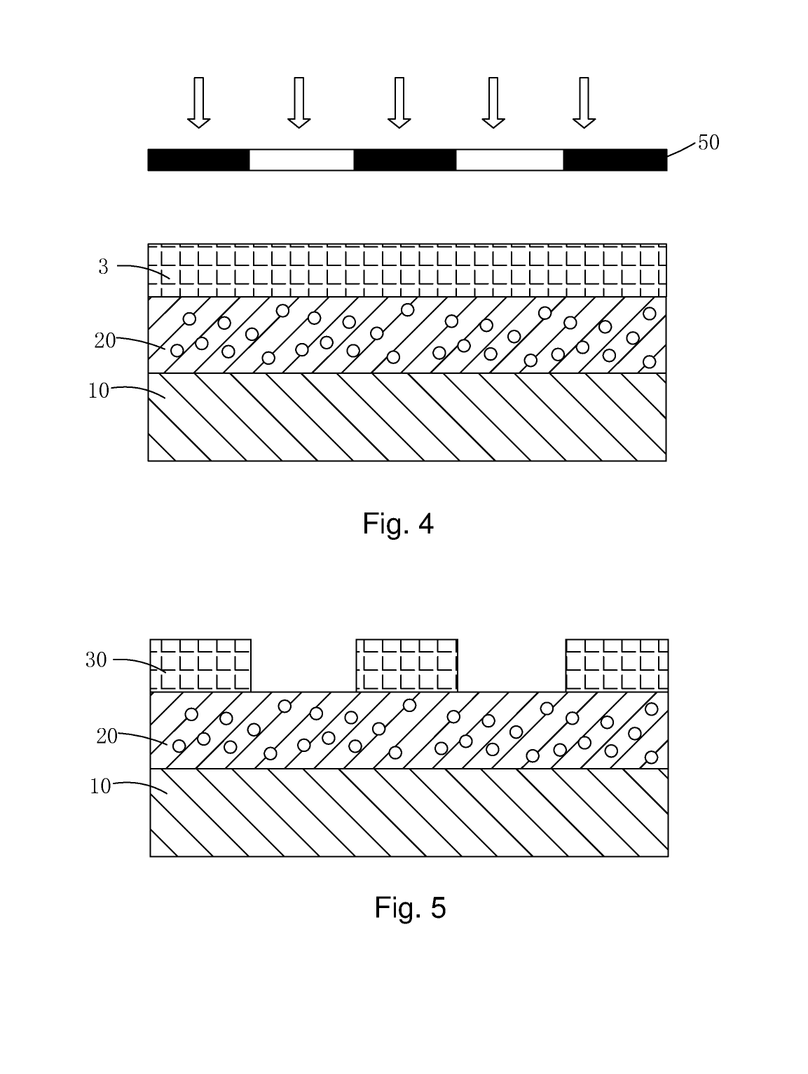

Referring to FIGS. 1-7, firstly, the present invention provides a method for patterning a quantum dot layer, which comprises the following steps:

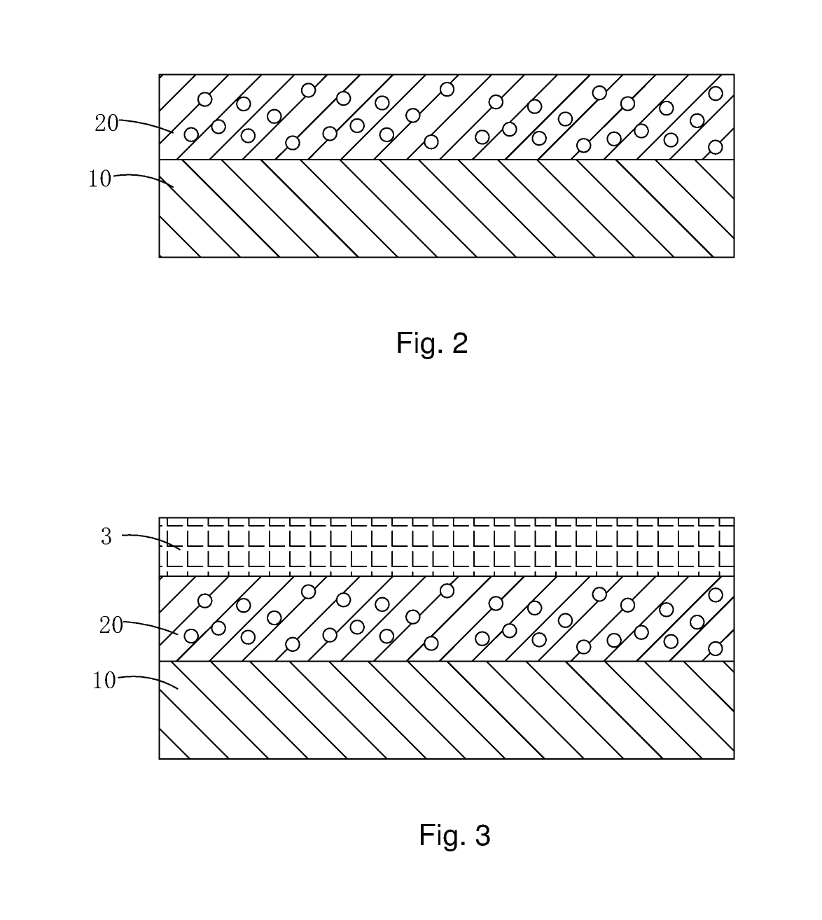

Step 1: as shown in FIG. 2, providing a base plate 10 and coating a monocolor quantum dot paste on the base plate 10 so as to obtain a monocolor quantum dot layer 20 after curing.

Specifically, the term monocolor used herein represents all kind of monochromatic colors, including red, green, and blue. The monocolor quantum dot layer 20, when excited by light, emits monochromatic light of a corresponding color, such as red light (of which the wavelength is 630-690 nm), green light (of which the wavelength is 500-560 nm), and blue light (of which the wavelength is 430-480 nm).

Specifically, the monocolor quantum dot paste comprises curable paste and monocolor quantum dots mixed in the curable paste. The curable paste can be heat curable paste or ultraviolet curable paste, and correspondingly, in this step, curing is achieved with a heat curing process or an ultraviolet curing process.

Specifically, the monocolor quantum dot paste comprises a monocolor quantum dot material that comprises one of II-VI group quantum dot materials and I-III-VI group quantum dot materials or multiple ones thereof. Preferably, the monocolor quantum dot material is one of CdSe, CdS, CdTe, ZnS, ZnSe, CuInS, and ZnCuInS or multiple ones thereof.

Specifically, the quantum dot layer 20 has a thickness of 1-50 μm.

Step 2: as shown in FIGS. 3-5, coating a photoresist on the monocolor quantum dot layer 20 to form a photoresist film 3 and applying a mask 50 to subject the photoresist film 3 to exposure and development and baking so as to form a photoresist layer 30.

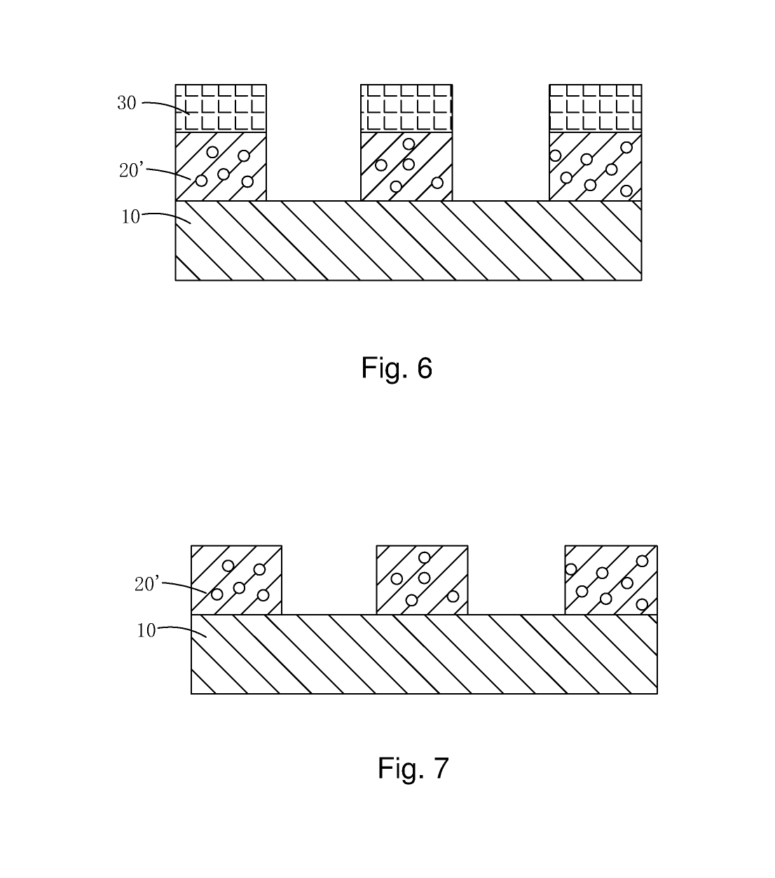

Step 3: as shown in FIG. 6, using the photoresist layer 30 as a shielding layer to subject the monocolor quantum dot layer 20 to etching for removing a portion of the monocolor quantum dot layer 20 that is not shielded by the photoresist layer 30 so as to form a patterned monocolor quantum dot layer 20′.

Specifically, in Step 3, the etching of the monocolor quantum dot layer 20 is conducted with dry etching or wet etching.

Specifically, in Step 2, the photoresist comprises a transparent material, and thus, the photoresist layer 30 so formed does not affect optical performance of the monocolor quantum dot layer 20′ formed in Step 3 so that there is no need to eventually peel off the photoresist layer 30.

Or alternatively, the photoresist may comprise a non-transparent material, and then, the method for patterning a quantum dot layer may further comprises: Step 4, as shown in FIG. 7, a peeling agent is applied to peel the photoresist layer 30 from the patterned monocolor quantum dot layer 20′.

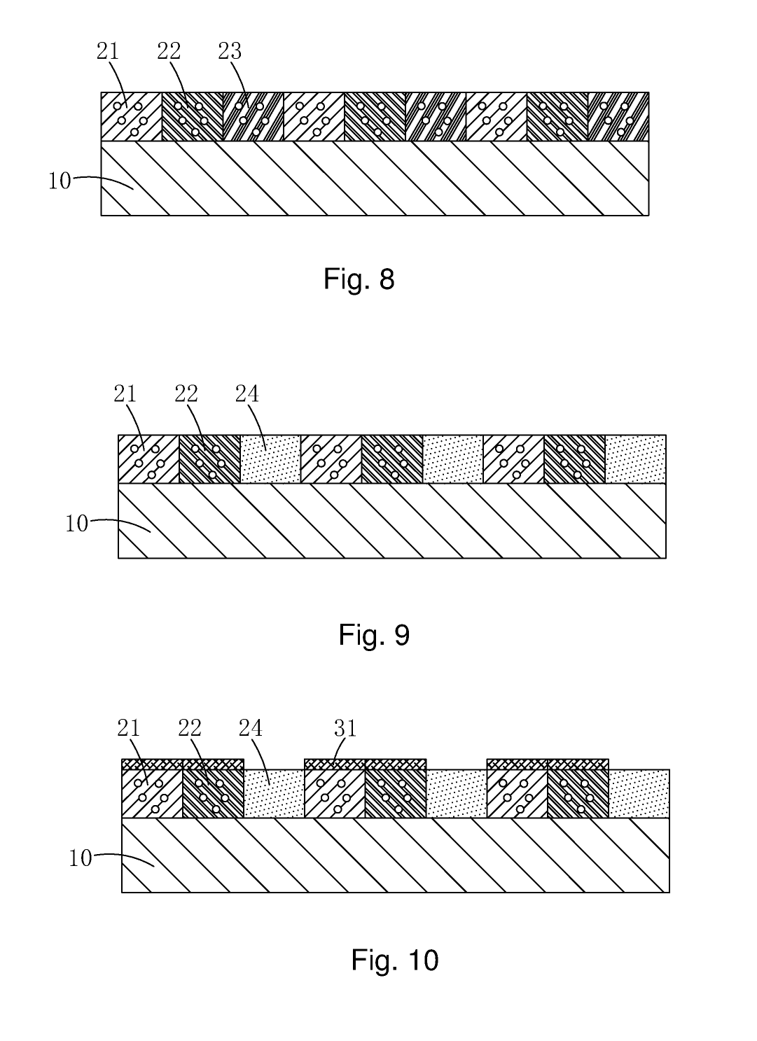

Referring to FIGS. 8-10, on the basis of the above-described method for patterning a quantum dot layer, the present invention further provides a method for manufacturing a quantum dot color filter, which comprises the following steps:

Step 1: providing a base plate 10, the base plate 10 comprising a red sub-pixel zone, a green sub-pixel zone, and a blue sub-pixel zone.

Step 2: forming, on the base plate 10, a patterned red quantum dot layer 21 corresponding to the red sub-pixel zone; a patterned green quantum dot layer 22 corresponding to the green sub-pixel zone; and a patterned blue quantum dot layer 23 or an organic transparent photoresist layer 24 corresponding to the blue sub-pixel zone.

The patterned red quantum dot layer 21, the patterned green quantum dot layer 22, and the patterned blue quantum dot layer 23 are formed with the above-described method for patterning a quantum dot layer by respectively applying a red quantum dot paste, a green quantum dot paste, and a blue quantum dot paste.

Referring to FIG. 8, a first example of the method for manufacturing a quantum dot color filter according to the present invention is illustrated, where the quantum dot color filter is used in a display device having ultraviolet backlighting, wherein in Step 2, a patterned blue quantum dot layer 23 is formed to correspond to the blue sub-pixel zone.

Referring to FIG. 9, a second example of the method for manufacturing a quantum dot color filter according to the present invention is illustrated, where the quantum dot color filter is used in a display device having blue backlighting, wherein in Step 2, an organic transparent photoresist layer 24 is formed to correspond to the blue sub-pixel zone. Further, as shown in FIG. 10, additionally included is Step 3, in which a blue light filter layer 31 is formed on each of the patterned red quantum dot layer 21 and the patterned green quantum dot layer 22 for filtering off unexcited blue light.

The quantum dot color filter manufactured with the method for manufacturing a quantum dot color filter according to the present invention is applicable as a color filter for an existing LCD (Liquid Crystal Display) device and may be set on one side of a color filter substrate of a display panel according to a regular structural arrangement, or the quantum dot color filter may be formed on one side of an array substrate of the display panel, this being an COA (Color filter On Array) arrangement, both being involved with a quantum dot display panel including the quantum dot color filter.

In summary, the present invention provides a method for patterning a quantum dot layer, which uses a photoresist layer having a patterned structure as a shielding layer to subject a monocolor quantum dot layer to etching to form a patterned quantum dot layer. The method simplifies the constituent components for making a quantum dot paste that is used to form a quantum dot layer and simplifying a surface chemical environment of the quantum dots to thereby increasing light emission efficiency of the quantum dot. Further, the method may manufacture a fine quantum dot pattern, greatly improving the resolution of the patterned quantum dot layer. The present invention also provides a method for manufacturing a quantum dot color filter, which is applied to manufacturing a quantum dot color filter on the basis of the above-described method for patterning a quantum dot layer and the quantum dot color filter so manufactured has a fine quantum dot pattern, the light emission efficiency of the quantum dots being high to thereby effectively improve the resolution and backlighting utilization of a display device.

Based on the description given above, those having ordinary skills of the art may easily contemplate various changes and modifications of the technical solution and technical ideas of the present invention and all these changes and modifications are considered within the protection scope of right for the present invention.

What is claimed is:

1. A method for patterning a quantum dot layer, comprising the following steps:
(1) providing a base plate and coating a monocolor quantum dot paste on the base plate so as to obtain a monocolor quantum dot layer after curing, the monocolor quantum dot layer emitting monochromatic light of a color corresponding thereto upon excited by external light;
(2) coating a photoresist on the monocolor quantum dot layer to form a photoresist film and applying a mask to subject the photoresist film to exposure and development and baking so as to form a photoresist layer; and
(3) using the photoresist layer as a shielding layer to subject the monocolor quantum dot layer to etching for removing a portion of the monocolor quantum dot layer that is not shielded by the photoresist layer so as to form a patterned monocolor quantum dot layer.

2. The method for patterning a quantum dot layer as claimed in claim 1, wherein the monocolor quantum dot paste comprises curable paste and monocolor quantum dots mixed in the curable paste; the curable paste comprises heat curable paste or ultraviolet curable paste; and in step (1), the curing is achieved with a heat curing process or an ultraviolet curing process.

3. The method for patterning a quantum dot layer as claimed in claim 2, wherein the monocolor quantum dot paste comprises a monocolor quantum dot material that comprises one of II-VI group quantum dot materials and I-III-VI group quantum dot materials or multiple ones thereof.

4. The method for patterning a quantum dot layer as claimed in claim 3, wherein the monocolor quantum dot material of the monocolor quantum dot paste comprises one of CdSe, CdS, CdTe, ZnS, ZnSe, CuInS, and ZnCuInS or multiple ones thereof.

5. The method for patterning a quantum dot layer as claimed in claim 1, wherein the monocolor quantum dot layer has a thickness of 1-50 μm; the photoresist comprises a transparent material; and the etching of the monocolor quantum dot layer in step (3) is conducted with dry etching or wet etching.

6. The method for patterning a quantum dot layer as claimed in claim 1, wherein the photoresist comprises a non-transparent material, and the method for patterning a quantum dot layer further comprises:
(4) applying a peeling agent to peel the photoresist layer from the patterned monocolor quantum dot layer.

7. A method for manufacturing a quantum dot color filter, comprising the following steps:
(1) providing a base plate, the base plate comprising a red sub-pixel zone, a green sub-pixel zone, and a blue sub-pixel zone; and
(2) forming, on the base plate, a patterned red quantum dot layer corresponding to the red sub-pixel zone; a patterned green quantum dot layer corresponding to the green sub-pixel zone; and a patterned blue quantum dot layer or an organic transparent photoresist layer corresponding to the blue sub-pixel zone,
wherein the patterned red quantum dot layer, the patterned green quantum dot layer, and the patterned blue quantum dot layer are respectively formed of a red quantum dot paste, a green quantum dot paste, and a blue quantum dot paste; and
wherein a patterning process for forming each of the patterned red quantum dot layer, the patterned green quantum dot layer, and the patterned blue quantum dot layer comprises the following steps:
(1′) providing a base plate and coating a monocolor quantum dot paste on the base plate so as to obtain a monocolor quantum dot layer after curing, the monocolor quantum dot layer emitting monochromatic light of a color corresponding thereto upon excited by external light;
(2′) coating a photoresist on the monocolor quantum dot layer to form a photoresist film and applying a mask to subject the photoresist film to exposure and development and baking so as to form a photoresist layer; and
(3′) using the photoresist layer as a shielding layer to subject the monocolor quantum dot layer to etching for removing a portion of the monocolor quantum dot layer that is not shielded by the photoresist layer so as to form a patterned monocolor quantum dot layer.

8. The method for manufacturing a quantum dot color filter as claimed in claim 7, wherein the monocolor quantum dot paste comprises curable paste and monocolor quantum dots mixed in the curable paste; the curable paste comprises heat curable paste or ultraviolet curable paste; and in step (1′), the curing is achieved with a heat curing process or an ultraviolet curing process.

9. The method for manufacturing a quantum dot color filter as claimed in claim 8, wherein the monocolor quantum dot paste comprises a monocolor quantum dot material that comprises one of II-VI group quantum dot materials and I-III-VI group quantum dot materials or multiple ones thereof.

10. The method for manufacturing a quantum dot color filter as claimed in claim 9, wherein the monocolor quantum dot material of the monocolor quantum dot paste comprises one of CdSe, CdS, CdTe, ZnS, ZnSe, CuInS, and ZnCuInS or multiple ones thereof.

11. The method for manufacturing a quantum dot color filter as claimed in claim 7, wherein the monocolor quantum dot layer has a thickness of 1-50 μm; the photoresist comprises a transparent material; and the etching of the monocolor quantum dot layer in step (3′) is conducted with dry etching or wet etching.

12. The method for manufacturing a quantum dot color filter as claimed in claim 7, wherein the photoresist comprises a non-transparent material, and the method for patterning a quantum dot layer further comprises:
(4′) applying a peeling agent to peel the photoresist layer from the patterned monocolor quantum dot layer.

13. The method for manufacturing a quantum dot color filter as claimed in claim 7, wherein the quantum dot color filter is applicable to a display device having blue backlighting and in step (2), an organic transparent photoresist layer is formed to correspond to the blue sub-pixel zone.

14. The method for manufacturing a quantum dot color filter as claimed in claim 13 further comprising: step (3) forming a blue light filter layer on each of the patterned red quantum dot layer and the patterned green quantum dot layer.

15. The method for manufacturing a quantum dot color filter as claimed in claim 7, wherein the quantum dot color filter is applicable to a display device having ultraviolet backlighting and in step (2), a patterned blue quantum dot layer is formed to correspond to the blue sub-pixel zone.
